(19) United States
(12) Patent Application Publication
(10) Pub. No.: US 2016/0276538 A1
(43) Pub. Date: Sep. 22, 2016

(54) Light Emitting Diodes With Current Spreading Material Over Perimetric Sidewalls

(71) Applicant: Toshiba Corporation, Tokyo (JP)

(72) Inventors: Wei Zhao, Dublin, CA (US); Chao-Kun Lin, San Jose, CA (US); Chih-Wei Chuang, Albany, CA (US)

(21) Appl. No.: 14/660,430

(22) Filed: Mar. 17, 2015

(51) Int. Cl. H01L 33/32; H01L 33/42; H01L 33/40; H01L 33/48; H01L 33/38; H01L 33/44

(52) U.S. Cl. CPC H01L 33/32; H01L 33/385; H01L 33/44; H01L 33/405; H01L 33/486; H01L 33/42

(57) ABSTRACT

A vertical light emitting diode (LED) assembly with current spreading material over one or more sidewalls of the LED is disclosed. In one embodiment, the vertical LED assembly includes an LED comprising a light emitting layer disposed between a first layer having a first conductivity type and a second layer have a second conductivity type. The vertical LED assembly further includes a substrate bonded to the LED and a first electrode disposed between the substrate and the LED and electrically coupled to the first layer of the LED. A second electrode is formed on a surface of the second layer of the LED opposite the first layer, and electrically coupled to the second layer. In one embodiment, the second electrode extends over one or more sidewalls of the LED. In one embodiment, the second electrode extends laterally beyond one or more sidewalls of the LED.

### FIELD OF THE INVENTION

This invention generally relates to light emitting diode (LED) assemblies, and more particularly, to LED assemblies with current spreading material formed over the perimetric sidewalls of the LED.

### BACKGROUND OF THE INVENTION

In general, light emitting diodes (LEDs) begin with a semiconductor growth substrate, typically a group III-V compound such as gallium nitride (GaN), gallium arsenide (GaAs), gallium phosphide (GaP), indium phosphide (InPO, and gallium arsenide phosphide (GaAsP). The semiconductor growth substrate may also be sapphire (Al₂O₃), silicon (Si) and silicon carbide (SiC) for group III-Nitride based LEDs, such as gallium nitride (GaN). Epitaxial semiconductor layers are grown on the semiconductor growth substrate to form the N-type and P-type semiconductor layers of the LED. A light emitting layer is formed at the interface between the N-type and P-type semiconductor layers of the LED.

The epitaxial layers may be formed by a number of developed processes including, for example, Liquid Phase Epitaxy (LPE), Molecular Beam Epitaxy (MBE), and Metal Organic Chemical Vapor Deposition (MOCVD). After the epitaxial semiconductor layers are formed, electrical contacts are coupled to the N-type and P-type semiconductor layers using known photolithography, etching, evaporation, and polishing processes. Individual LEDs are diced and mounted to a package with wire bonding. An encapsulant is deposited onto the LED and the LED is sealed with a protective lens which also aids in light extraction. When a voltage is applied to the electrical contacts, a current will flow between the contacts, causing photons to be emitted by the light emitting layer.

There are a number of different types of LED assemblies, including lateral LEDs, vertical LEDs, flip-chip LEDs, and hybrid LEDs (a combination of the vertical and flip-chip LED structure). Typically, vertical LED assemblies utilize a reflective contact between the LED and the underlying substrate to reflect photons which are generated downwards by the light emitting layer towards the substrate. By using a reflective contact, more photons are allowed to escape the LED rather than be absorbed by the substrate, improving the overall light power output and light output efficiency of the vertical LED assembly.

A conventional vertical LED assembly is shown in FIGS. 1A and 1B. FIG. 1A is a plan view of an LED assembly 100 in the prior art, and FIG. 1B is a cross-sectional view of the LED assembly 100 of FIG. 1A taken along the axis AA. In FIG. 1A, an N-electrode 112 is formed on a top surface of an N-type semiconductor layer 108, and electrically coupled to the N-type semiconductor layer 108. As shown in FIG. 1B, underlying the N-type semiconductor layer 108 is a light emitting layer 106, and a P-type semiconductor layer 104. Taken together, the N-type semiconductor layer 108, the light emitting layer 106, and the P-type semiconductor layer 104 comprise LED 101 of the LED assembly 100. As previously discussed, a reflective P-electrode 110 is disposed between the P-type semiconductor layer 104 and substrate 102. A bonding layer 113 attaches the LED 101 to the substrate 102.

As shown in FIGS. 1A and 1B, the N-electrode 112 is formed around the edge of a surface 103 of the N-type semiconductor layer 108, inwards of an upper edge 117 of the surface 103 and a bottom edge 115, and with a portion extending down the middle of the surface 103 of the N-type semiconductor layer 108. The N-electrode 112 is formed in this manner to minimize the absorption of photons emitted by the light emitting layer 106 while attempting to maintain uniform current spreading throughout the LED 101. The more area of the surface 103 of the N-type semiconductor layer 108 the N-electrode 112 covers, the more photons that will be absorbed by the N-electrode 112—reducing the overall light output power and light output efficiency of the LED assembly 100. However, minimizing the size of the N-electrode 112 also comes with tradeoffs. While fewer photons may be absorbed by the N-electrode 112 if it is smaller and covers less of the surface of the N-type semiconductor layer, a small N-electrode 112 will have a higher sheet resistance due to the smaller amount of conductive material used to form the electrode, requiring more voltage to power the LED assembly 100 and reducing the wall plug efficiency (the ratio of the light output power of the LED compared to the electrical power (I×V) of the LED) of the LED assembly 100. Correspondingly, the N-electrode 112 will also suffer from increased current crowding effects as the smaller N-electrode 112 will be less efficient at evenly distributing the injected current throughout the LED 101 of the LED assembly 100, also reducing the wall plug efficiency of the LED assembly 100. At increasingly higher power, the current crowding effects will become more pronounced, and the wall plug efficiency will begin to drop at an accelerated rate.

There is, therefore, an unmet demand for vertical LED assemblies with improved current spreading and improved wall plug efficiency without sacrificing light output power and light output uniformity, particularly for high-power applications.

### BRIEF DESCRIPTION OF THE INVENTION

In one embodiment, a vertical light emitting diode (LED) assembly includes an LED comprising a light emitting layer disposed between a first layer having a first conductivity type and a second layer having a second conductivity type. In one embodiment, the first layer is a P-type semiconductor material and the second layer is an N-type semiconductor material. In another embodiment, the first layer is an N-type semiconductor material and the second layer is a P-type semiconductor material.

The vertical LED assembly further includes a substrate bonded to the LED. A first electrode is disposed between the LED and the substrate, the first electrode being electrically coupled to the first layer of the LED. The first electrode forms an ohmic contact with the first layer. In one embodiment, the first electrode comprises a material having an optical reflectivity greater than 80%. In one embodiment, the first electrode comprises silver (Ag). The vertical LED assembly further includes a second electrode disposed on a surface of the second layer opposite the first layer, the second electrode electrically coupled to the second layer. The second electrode forms an ohmic contact with the second layer.

In one embodiment, the second electrode extends from the surface of the second layer over one or more sidewalls of the LED. In one embodiment, the second electrode extends over each of the one or more sidewalls of the LED. An insulating layer is disposed between the second electrode and the one or more sidewalls of the LED. In one embodiment, the second electrode extends laterally beyond one or more sidewalls of the LED. In one embodiment, the second electrode extends laterally beyond each of the one or more sidewalls of the LED.

In another embodiment, a third electrode is disposed over one or more sidewalls of the LED and electrically coupled to the second electrode on the surface of the second layer. The third electrode and the second electrode form an ohmic contact. In one embodiment, the third electrode is disposed over each of the one or more sidewalls of the LED. In one embodiment, an insulating layer is disposed between the third electrode and the one or more sidewalls of the LED. In one embodiment, the third electrode extends laterally beyond the one or more sidewalls of the LED. In one embodiment, the second electrode extends laterally beyond each of the one or more sidewalls of the LED. In one embodiment, the second electrode and third electrodes comprise different materials. In one embodiment, the third electrode has a thickness greater than the second electrode. In one embodiment, the ratio of the thickness of the third electrode compared to the thickness of the second electrode is 2:1, or greater. In one embodiment, the thickness of the third electrode compared to the thickness of the second electrode is 5:1, or greater.

During device operation of the vertical LED assembly, the additional electrode material formed over the one or more sidewalls of the LED provides enhanced current spreading and a lower sheet resistance, decreasing the amount of forward voltage (Vf) required to operate the vertical LED assembly and increasing the wall plug efficiency of the vertical LED assembly.

### BRIEF DESCRIPTION OF THE FIGURES

FIG. 1A shows a plan view of a vertical LED assembly in the prior art.

FIG. 1B shows a cross-sectional view of the LED assembly of FIG. 1A.

FIG. 2A shows a plan view of a vertical LED assembly with current spreading over a sidewall of the LED, according to one embodiment of the invention.

FIG. 2B shows a cross-sectional view of the LED assembly of FIG. 2A.

FIG. 2C shows another cross-sectional view of the LED assembly of FIG. 2A.

FIG. 3A shows a plan view of a vertical LED assembly with current spreading over each sidewall of the LED, according to one embodiment of the invention.

FIG. 3B shows a cross-sectional view of the LED assembly of FIG. 3A.

FIG. 3C shows another cross-sectional view of the LED assembly of FIG. 3A.

FIG. 4A shows a plan view of a vertical LED assembly with current spreading over each sidewall of the LED, according to another embodiment of the invention.

FIG. 4B shows a cross-sectional view of the LED assembly of FIG. 4A.

FIG. 4C shows another cross-sectional view of the LED assembly of FIG. 4A.

FIGS. 5A-M shows cross-sectional views of the manufacturing steps for producing the vertical LED assemblies of FIGS. 3A and 4A.

### DETAILED DESCRIPTION OF THE INVENTION

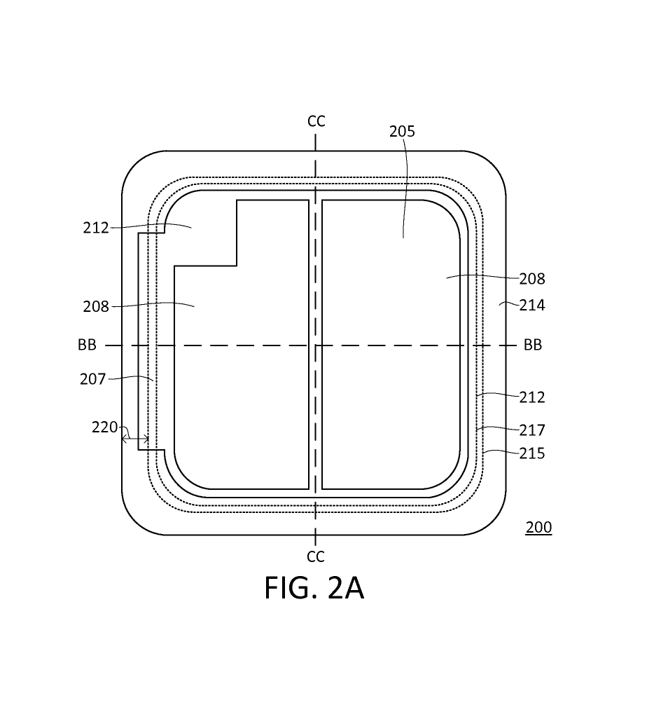

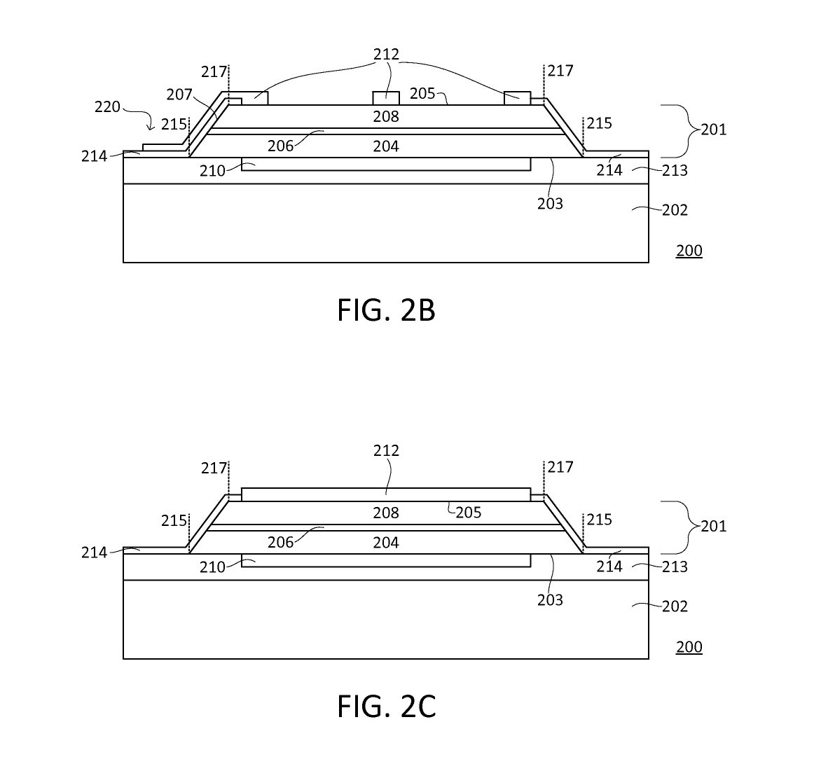

FIG. 2A shows a plan view of an LED assembly 200 with current spreading over a sidewall of the LED, according to one embodiment of the invention. FIG. 2B shows a cross-sectional view of the LED assembly 200 of FIG. 2A taken along the axis BB. FIG. 2C shows another cross-sectional view of the LED assembly 200 of FIG. 2A taken along the axis CC. As shown in FIGS. 2A-2C, a light emitting layer 206 is disposed between a first semiconductor layer 204 and a second semiconductor layer 208. The first semiconductor layer 204, the second semiconductor layer 208, and the light emitting layer 206 comprise LED 201 of the LED assembly 200. The first semiconductor layer 204 and the second semiconductor layer 208 may comprise any suitable semiconductor material, for example, group III-V compounds such as gallium nitride (GaN), gallium arsenide (GaAs), gallium phosphide (GaP), indium phosphide (InP), or gallium arsenide phosphide (GaAsP). In one embodiment, the first semiconductor layer 204 comprises a P-type semiconductor material, and the second semiconductor layer 208 comprises an N-type semiconductor material. In another embodiment, the first semiconductor layer 204 comprises an N-type semiconductor material, and the second semiconductor layer 208 comprises a P-type semiconductor material.

A first electrode 210 is formed on a bottom surface 203 of the first semiconductor layer 204, between the first semiconductor layer 204 and substrate 202. The first electrode 210 covers a substantial portion of the bottom surface 203 of the first semiconductor layer 204, and forms an ohmic contact with the first semiconductor layer 204. Preferably, the first electrode 210 comprises a material having a high degree of optical reflectivity to reflect the photons which are generated downwards from the light emitting layer 206 towards the substrate 202 so the photons have a greater chance of escaping the LED 201, improving the wall plug efficiency of the LED assembly 200. In one embodiment, the reflective material has an optical reflectivity greater than 80% in the visible wavelength range. In one embodiment, the first electrode 210 comprises silver (Ag). In other embodiments, the first electrode 210 may comprise aluminum (Al), or gold (Au).

A bonding layer 213 bonds the LED 201 to the substrate 202. In one embodiment, the bonding layer 213 is a conductive material suitable for conventional wafer bonding processes, such as eutectic bonding where heat and pressure are used to form an ohmic connection between the bonding layer 213, the first electrode 210, and the first semiconductor layer 204. In one embodiment, the bonding layer 213 comprises gold tin (AuSn). In other embodiments, the bonding layer 213 may comprise copper tin (CuSn), or silicon gold (SiAu). In one embodiment, the bonding layer 213 is a non-conductive adhesive material, such as benzocyclobutene (BCB).

A second electrode 212 is formed on a top surface 205 of the second semiconductor layer 208. The second electrode 212 comprises a material suitable for forming an ohmic contact with the second semiconductor layer 208. In one embodiment, the second electrode 212 comprises a metal, such as silver (Ag), gold (Ag), or aluminum (Al). In another embodiment, the second electrode 212 comprises a conductive compound, such as indium tin oxide (ITO). As shown in FIGS. 2A-2C, a portion of the second electrode 212 extends over an upper edge 217 of the top surface 205 of the second semiconductor layer 208, and extends down a sidewall 207 of the LED 201. The second electrode 212 further extends past a bottom edge 215 of the sidewall 207 and into a street 220 of the LED assembly 200. The street 220 is commonly understood to be the region above the substrate 202 of the LED assembly 200 outside of the bottom edges 215 of the LED 201.

An insulating layer 214 is formed between the second electrode 212 and the sidewall 207 of the LED 201 and the bonding layer 213 in the street of the LED assembly 200, to prevent shorting the second electrode 212 with the first semiconductor layer 204, the first electrode 210, and the barrier layer 213. Without the insulating layer 214 between the second electrode 212 and the sidewall 207 of the LED 201, the LED 201 would not function properly. As such, the insulating layer 214 preferably extends the entire length of the sidewall 207 of the LED 201, from upper edge 217 of the top surface 205 of the second semiconductor layer 208, down to the bottom edge 215 of sidewall 207, and into the street 220 of the LED assembly 200. To ensure the insulating layer 214 adequately protects against shorting, the insulating layer 214 may be formed inwards of the upper edge 217 of the top surface 205 of the second semiconductor layer 208 such that the insulating layer 214 covers a portion of the top surface 205. This way, even if there are variations in the manufacturing process and the formation of the insulating layer 214 is not aligned as designed, the insulating layer 214 should still extend far enough over the sidewall 207 of the LED 201 to properly insulate the second electrode 212 from shorting against the first semiconductor layer 204, the first electrode 210, and the barrier layer 213.

As another level of protection against shorting, the insulating layer 214 is preferably formed to be a high-quality layer, with few defects or pinholes through the insulating layer 214 which could cause current to leak from the second electrode 212 to the underlying bonding layer 213 or sidewall 207 of the LED 201. The quality of the insulating layer 214 depends on the materials used and the thickness of the layer. In one embodiment, the insulating layer 214 comprises silicon nitride (SiNₓ). In another embodiment, the insulating layer 214 comprises silicon dioxide (SiO₂). In one embodiment, the insulating layer 214 is between 0.2 μm to 1 μm in thickness.

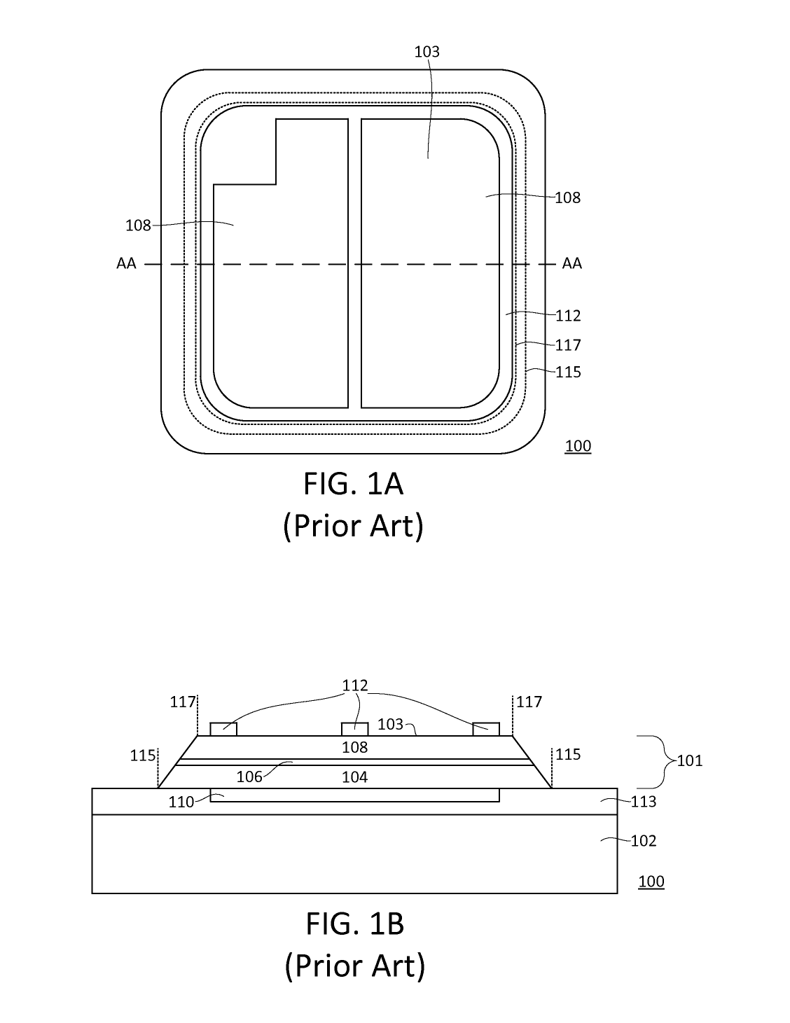

During device operation of the LED assembly 200, when a sufficient forward voltage (Vf) is applied to the first electrode 210 and the second electrode 212, a current will flow through the LED 201 between the first electrode 210 and the second electrode 212, causing photons to be emitted by the light emitting layer 206. Because the second electrode 212 extends over an upper edge 217 of the top surface 205 of the second semiconductor layer 208, down a sidewall 207 of the LED 201, and past a bottom edge 215 of the sidewall 207 into a street of the LED assembly 200, the second electrode 212 of the LED assembly 200 utilizes more conductive material compared with the N-electrode 112 of the prior art LED assembly 100 shown in FIGS. 1A and 1B having similar dimensions and comprising similar materials. As such, the sheet resistance of the second electrode 212 will be decreased, requiring less forward voltage (Vf) to operate the LED assembly 200. Moreover, the overall light output of the LED 201 is not decreased as the second electrode 212 does not cover much, if any, additional area on the top surface 205 of the LED 201, but rather extends down the sidewall 207 of the LED 201 where no light is emitted.

The current spreading through the portion of the second electrode 212 which extends down the sidewall 207 of the LED 201 will also be improved due to the increased amount of conductive material used. Improved current spreading means that the light generation along the edge of the LED assembly 200, where the second electrode 212 extends down the sidewall 207 of the LED 201, will be more uniform, improving the light output uniformity of the LED 201 along that edge. Thus, the LED assembly 200 will realize improved light output uniformity, reduced forward voltage (Vf), and better wall plug efficiency compared to the LED assembly 100 of the prior art. Moreover, the improvement in the performance of the LED assembly 200 will further increase at increasing power, due to reduced current crowding as a result of better current spreading through the second electrode 212.

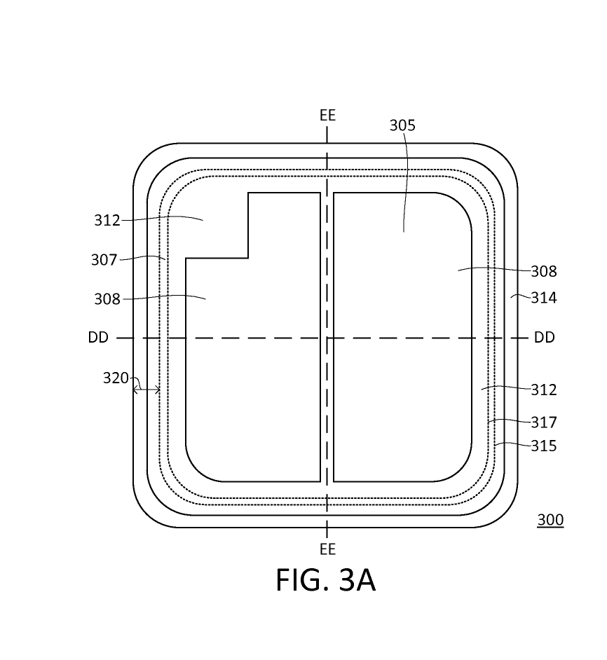

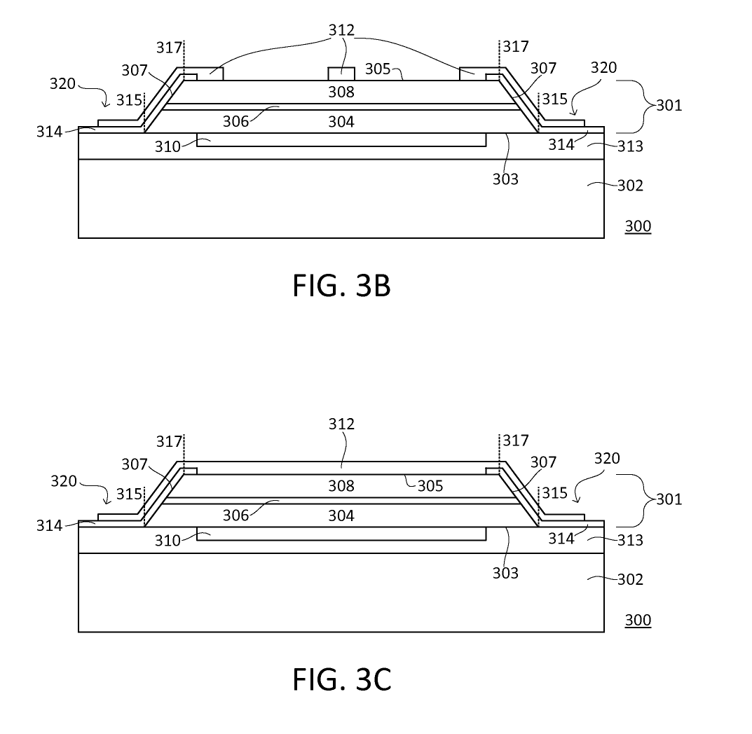

FIG. 3A shows a plan view of a vertical LED assembly 300 with current spreading over each sidewall of the LED, according to one embodiment of the invention. FIG. 3B shows a cross-sectional view of the LED assembly 300 of FIG. 3A taken along the axis DD. FIG. 3C shows another cross-sectional view of the LED assembly 300 of FIG. 3A taken along the axis EE. Similar to the LED assembly 200 of FIGS. 2A-2C, as shown in FIGS. 3A-3C, a light emitting layer 306 is disposed between a first semiconductor layer 304 and a second semiconductor layer 308. The first semiconductor layer 304, the second semiconductor layer 308, and the light emitting layer 306 comprise LED 301 of the LED assembly 300. In one embodiment, the first semiconductor layer 304 comprises a P-type semiconductor material, and the second semiconductor layer 308 comprises an N-type semiconductor material. In another embodiment, the first semiconductor layer 304 comprises an N-type semiconductor material, and the second semiconductor layer 308 comprises a P-type semiconductor material.

A first electrode 310 is formed on a bottom surface 303 of the first semiconductor layer 304, between the first semiconductor layer 304 and substrate 302. The first electrode 310 covers a substantial portion of the bottom surface 303 of the first semiconductor layer 304, and forms an ohmic contact with the first semiconductor layer 304. In one embodiment, the first electrode 310 comprises a reflective material having an optical reflectivity greater than 80% in the visible wavelength range. In one embodiment, the first electrode 310 comprises silver (Ag). In other embodiments, the first electrode 310 may comprise aluminum (Al), or gold (Au).

A bonding layer 313 bonds the LED 301 to the substrate 302. The bonding layer 313 forms an ohmic connection with the first electrode 310, and the first semiconductor layer 304. In one embodiment, the bonding layer 313 comprises gold tin (AuSn). In other embodiments, the bonding layer 313 may comprise copper tin (CuSn), or silicon gold (SiAu).

A second electrode 312 is formed on a top surface 305 of the second semiconductor layer 308. The second electrode 312 comprises a material suitable for forming an ohmic contact with the second semiconductor layer 308. In one embodiment, the second electrode 312 comprises a metal, such as silver (Ag), gold (Ag), nickel (Ni), platinum (Pt), chromium (Cr), palladium (Pd), or aluminum (Al). In another embodiment, the second electrode 312 comprises a conductive compound, such as indium tin oxide (ITO). As shown in FIGS. 3A-3C, the second electrode 312 extends over upper edges 317 of the top surface 305 of the second semiconductor layer 308, extends down each sidewall 307 of the LED 301, and extends past bottom edges 315 of the sidewalls 307 into the streets 320 of the LED assembly 300.

An insulating layer 314 is formed between the second electrode 312 and the sidewall 307 of the LED 301 and the bonding layer 313 in the street of the LED assembly 300. The insulating layer 314 may be formed inwards of the upper edges 317 of the top surface 305 of the second semiconductor layer 308 such that the insulating layer 314 covers a portion of the top surface 305. In one embodiment, the insulating layer 314 comprises silicon nitride (SiNₓ). In another embodiment, the insulating layer 314 comprises silicon dioxide (SiO₂). In one embodiment, the insulating layer 314 is between 0.2 μm to 1 μm in thickness.

Because the second electrode 312 extends over each sidewall 307 of the LED 301 and into the streets of the LED assembly 300, the LED assembly 300 will realize even better wall plug efficiency and light output uniformity compared with the LED assembly 200. The further increase in conductive material comprising the second electrode 312 results in even lower sheet resistance and improved current spreading throughout each edge of the LED 301. As previously discussed, because the LED 301 does not emit light from the sidewalls 307, extending the second electrode 312 over the sidewalls 307 will not result in a decrease in light output power of the LED assembly 300.

During testing at an operating current of 1 Amp, the LED assembly 300 with the second electrode 312 having a width of 25 μm extending from the top surface 305 of the second semiconductor layer 308 down the sidewalls 307 and into the street 320, the LED assembly 300 was observed to have a 19 mV lower Vf compared to the prior art LED assembly 100 in FIGS. 1A and 1B with the second electrode 112 having a width of 8 μm which does not extend down the sidewalls, with identical light output power. Even greater improvement will be seen at higher operating currents due to the improved current spreading of the second electrode 312 compared with the N-electrode 112 of the prior art LED assembly 100 without current spreading over the sidewalls of the LED 101.

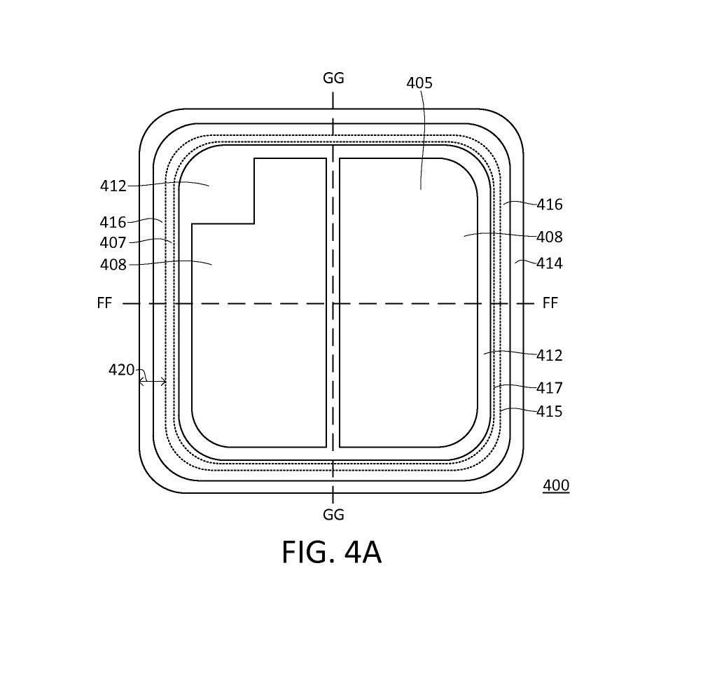

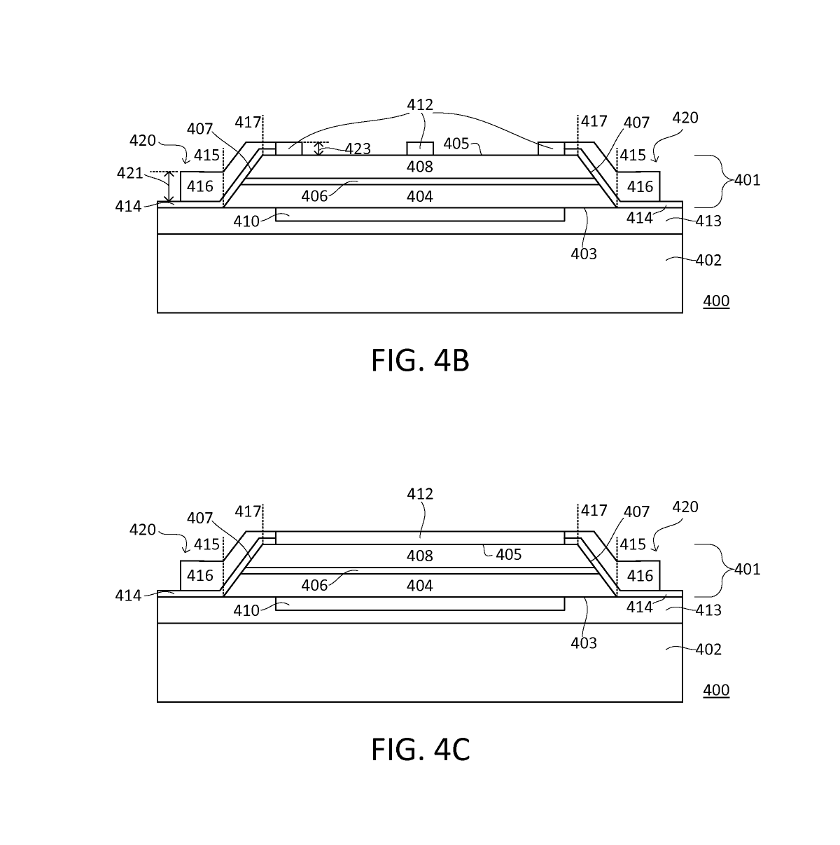

FIG. 4A shows a plan view of a vertical LED assembly 400 with current spreading over each sidewall of the LED, according to another embodiment of the invention. FIG. 4B shows a cross-sectional view of the LED assembly 400 of FIG. 4A taken along the axis FF. FIG. 4C shows another cross-sectional view of the LED assembly 400 of FIG. 4A taken along the axis GG. Similar to the LED assembly 200 of FIGS. 2A-2C and the LED assembly 300 of FIGS. 3A-3C, as shown in FIGS. 4A-4C, LED 401 comprises a light emitting layer 406 disposed between a first semiconductor layer 404 and a second semiconductor layer 408. In one embodiment, the first semiconductor layer 404 comprises a P-type semiconductor material, and the second semiconductor layer 408 comprises an N-type semiconductor material. In another embodiment, the first semiconductor layer 404 comprises an N-type semiconductor material, and the second semiconductor layer 408 comprises a P-type semiconductor material.

A first electrode 410 is formed on a bottom surface 403 of the first semiconductor layer 404, between the first semiconductor layer 404 and substrate 402. The first electrode 410 covers a substantial portion of the bottom surface 403 of the first semiconductor layer 404, and forms an ohmic contact with the first semiconductor layer 404. In one embodiment, the first electrode 410 comprises a reflective material having an optical reflectivity greater than 80% in the visible wavelength range. In one embodiment, the first electrode 410 comprises silver (Ag). In other embodiments, the first electrode 410 may comprise aluminum (Al), or gold (Au).

A bonding layer 413 bonds the LED 401 to the substrate 402. The bonding layer 413 forms an ohmic connection with the first electrode 410, and the first semiconductor layer 404. In one embodiment, the bonding layer 413 comprises gold tin (AuSn). In other embodiments, the bonding layer 413 may comprise copper tin (CuSn), or silicon gold (SiAu).

A second electrode 412 is formed on a top surface 405 of the second semiconductor layer 408. The second electrode 412 comprises a material suitable for forming an ohmic contact with the second semiconductor layer 408. A third electrode 416 is formed over upper edges 417 of the top surface 405 of the second semiconductor layer 408, extending down each sidewall 407 of the LED 401, and extending past bottom edges 415 of the sidewalls 407 into the streets 420 of the LED assembly 400. The third electrode 416 and the second electrode 412 are electrically coupled together. By forming the third electrode 416 over the sidewalls 407 of the LED 401, the third electrode 416 and the second electrode 412 can comprise different materials.

It is generally understood that forming a good ohmic contact on a surface of a doped semiconductor material requires careful selection of the material and processes used. In some circumstances, expensive high-quality materials must be used, such as gold (Au), silver (Ag), or platinum (Pt). In some circumstances, those materials which are able to form a good contact on the top surface 405 of the second semiconductor layer 408 may not be able to form a good contact over insulating layer 414 covering the sidewalls 407 of the LED. For example, silver (Ag) is able to form an ohmic contact with the second semiconductor layer 408, however silver (Ag) does not have good adhesion with silicon dioxide (SiO₂), as the silver (Ag) may peel off from the silicon dioxide (SiO₂). As such, the second electrode 412 may comprise silver (Ag), and the third electrode 416 formed over the insulating layer 414 may comprise a different material than silver (Ag) which is suitable for forming a good contact with the silicon dioxide (SiO₂) insulating layer, for example indium tin oxide (ITO). In addition, the third electrode 416 may comprise a different low quality or less expensive material, such as indium tin oxide (ITO). By using only the high-quality material for the second electrode 412, and a lower cost conductive material for the third electrode 416, the overall cost of the LED assembly 400 may be reduced.

Therefore, in one embodiment, the second electrode 412 may comprise gold (Au) or silver (Ag), and the third electrode 416 may comprise a different material, such as indium tin oxide (ITO), aluminum (Al), or any other conductive material suitable for being formed over the insulating layer 414. By using a suitable material for the second electrode 412, and a different suitable material for the third electrode 416, the overall reliability of the LED assembly 400 may be improved. In other embodiments, the second electrode 412 and the third electrode 416 may comprise titanium (Ti), chromium (Cr), nickel (Ni), or palladium (Pd).

By electrically coupling the third electrode 416 and the second electrode 412, they will behave as a single electrode during device operation of the LED assembly 400. As such, in one embodiment, the second electrode 412 can be formed thinly, and a thicker third electrode 416 will compensate for the loss of sheet resistance due to the reduction of the amount of material used for the second electrode 412. As shown in FIG. 4B, in one embodiment, the second electrode 412 has a thickness 423, which is thinner than the third electrode 416 having a thickness 421. A thinner second electrode 412 will also reduce the overall height of the LED assembly 400, making the LED assembly 400 more compact and better suited for applications requiring a thinner profile.

An insulating layer 414 is formed between the third electrode 416 and the sidewall 407 of the LED 401 and the bonding layer 413 in the street of the LED assembly 400. The insulating layer 414 may be formed inwards of the upper edges 417 of the top surface 405 of the second semiconductor layer 408 such that the insulating layer 414 covers a portion of the top surface 405. In one embodiment, the insulating layer 414 comprises silicon nitride (SiNₓ). In another embodiment, the insulating layer 414 comprises silicon dioxide (SiO₂). In one embodiment, the insulating layer 414 is between 0.2 μm to 1 μm in thickness.

As previously discussed, in one embodiment, the third electrode 416 may be formed to a greater thickness that the second electrode 402 resulting in even further improvement in the wall plug efficiency due to lower sheet resistance of the combination of the second electrode 412 and the third electrode 416 and improved current spreading as more conductive material is used overall, which in turn, reduced the Vf required to operate the LED assembly 400. In one embodiment, the ratio of the thickness of the third electrode 416 compared to the thickness of the second electrode 412 is 2:1, or greater. In another embodiment, the ratio of the thickness of the third electrode 416 compared to the thickness of the second electrode 412 is 5:1, or greater.

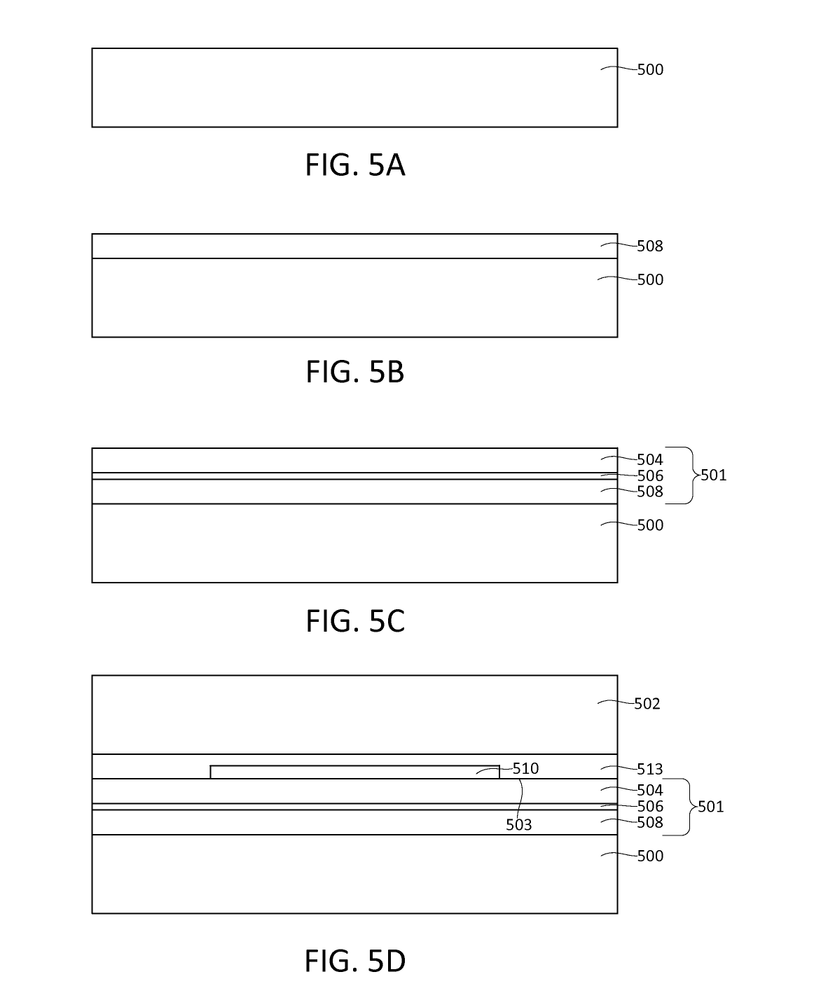

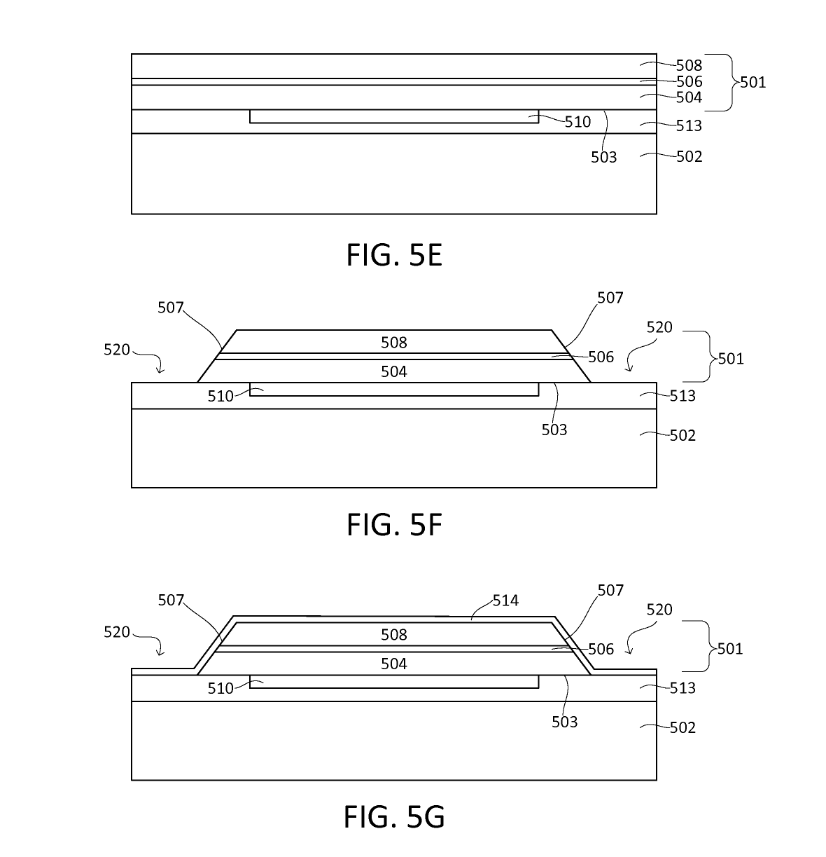

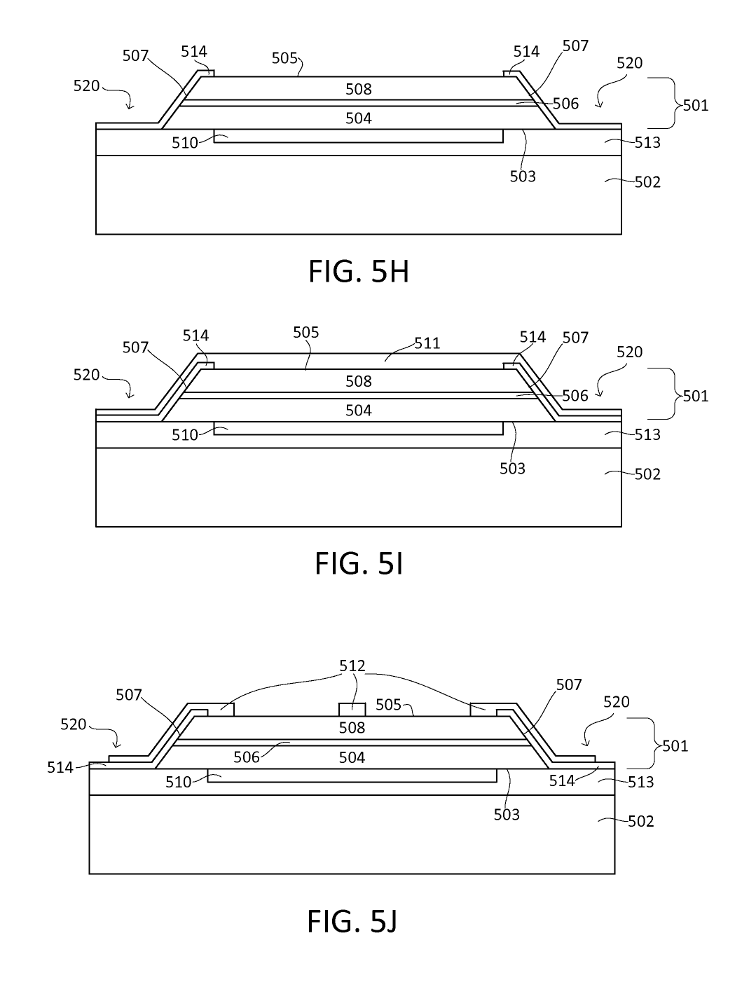

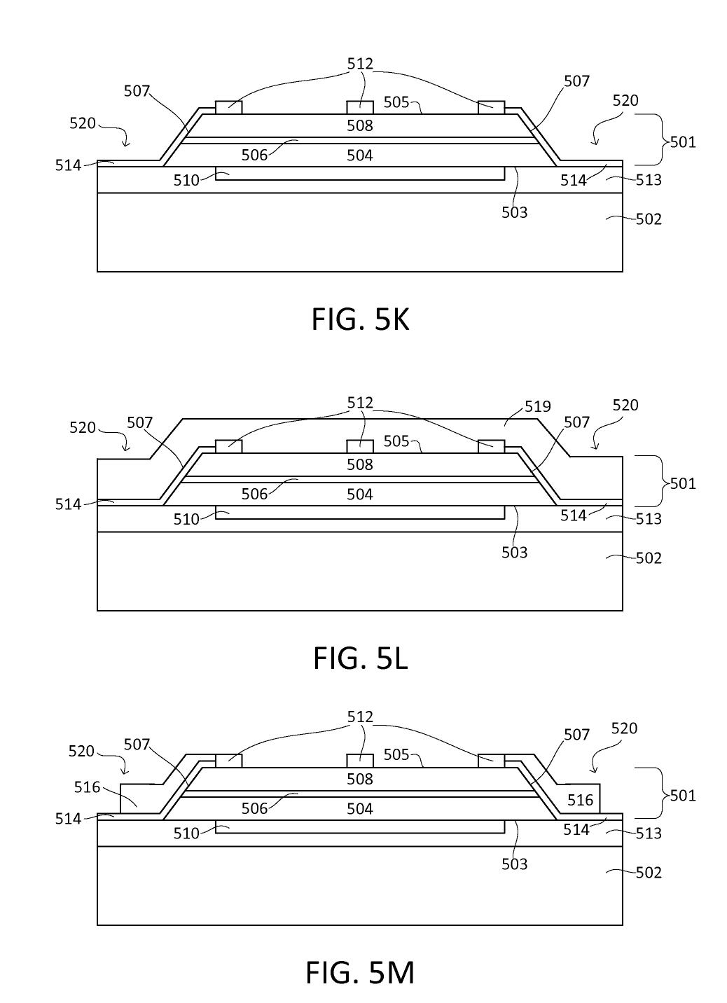

FIGS. 5A-5M shows cross-sectional views of the manufacturing steps for producing the vertical LED assemblies of FIGS. 3A and 4A. In FIG. 5A, a growth substrate 500 is provided. Growth substrate 500 is typically a wafer, and may comprise any material suitable for epitaxially growing layers of group III-V compounds. In one embodiment, growth substrate 500 comprises bulk gallium nitride (GaN). In other embodiments, growth substrate 500 may comprise gallium arsenide (GaAs), gallium phosphide (GaP), indium phosphide (InP), gallium arsenide phosphide (GaAsP), sapphire (Al₂O₃), silicon (Si) or silicon carbide (SiC).

In FIG. 5B, a second semiconductor layer 508 is epitaxially grown on a surface of the growth substrate 500. The second semiconductor layer 508 comprises a group III-V compound, such as gallium nitride (GaN) gallium arsenide (GaAs), gallium phosphide (GaP), indium phosphide (InP), or gallium arsenide phosphide (GaAsP). In one embodiment, the second semiconductor layer 508 comprises an N-type semiconductor material. In another embodiment, the second semiconductor layer 508 comprises a P-type semiconductor material. The second semiconductor layer 508 may be grown using any known growth method, including Metal Organic Chemical Vapor Deposition (MOCVD), Molecular Beam Epitaxy (MBE), or Liquid Phase Epitaxy (LPE).

In FIG. 5C, a first semiconductor layer 504 is epitaxially grown on top of the second semiconductor layer 508. The first semiconductor layer 504 comprises the same semiconductor material as the second semiconductor layer 508 having a conductivity type opposite that of the second semiconductor layer 508. For example, in one embodiment, the second semiconductor layer 508 comprises an N-type semiconductor material and the first semiconductor layer 504 comprises a P-type semiconductor material. In another embodiment, the second semiconductor layer 508 comprises a P-type semiconductor material and the first semiconductor layer 504 comprises an N-type semiconductor material. For example, in one embodiment, the second semiconductor layer 508 comprises N-type gallium nitride (GaN) and the first semiconductor layer 504 comprises P-type gallium nitride (GaN). A light emitting layer 506 is formed at the interface of the first and second semiconductor layers 504 and 508. The first semiconductor layer 504, the light emitting layer 506, and the second semiconductor layer 508 comprise an LED 501.

In FIG. 5D, a handling substrate 502 (e.g., a wafer) is bonded to a surface 503 of the first semiconductor layer 504 of the LED 501. The bonding is accomplished using any known wafer bonding process, such as eutectic bonding where a bonding layer 513 is heated and pressure is applied to bond the handling substrate 502 to the LED 501. A first electrode 510 is included in the bonding layer 513 the eutectic bonding process causes an ohmic contact to be formed between the first electrode 510 and the first semiconductor layer 504. In one embodiment, the bonding layer 513 and the first electrode 510 are first deposited on the surface 503 of the first semiconductor layer 504 and then the handling wafer 502 is eutectically bonded to the bonding layer 503 deposited on the LED 501. In another embodiment, the bonding layer 513 and the first electrode 510 are first deposited on a surface of the handling substrate 502 and then the handling substrate 502 along with the bonding layer 513 and the first electrode 510 are eutectically bonded to the LED 501.

As previously discussed in connection with FIGS. 2A-C, 3A-C, and 4A-C, the first electrode 510 comprises a reflective material, such as silver (Ag), to reflect photons emitted downwards towards the handling substrate 502 by the light emitting layer 506. In FIG. 5E, the growth substrate 500 is removed using any known method. In one embodiment, the growth substrate 500 is removed using a chemical etching. In another embodiment, the growth substrate 500 is removed using Laser Lift Off (LLO). In yet another embodiment, the growth substrate 500 is removed using mechanical grinding.

In FIG. 5F, the first semiconductor layer 504, the light emitting layer 506, and the second semiconductor layer 508 of the LED 501 are etched to form a mesa structure with sidewalls 507. The LED 501 is formed into the mesa structure because, prior to this step, the first semiconductor layer 504, the light emitting layer 506, and the second semiconductor layer 508 were formed as continuous layers across the handling substrate 502, which as previously mentioned is a wafer. As is commonly known, a wafer typically comprises a plurality of individual semiconductor die, which after processing, will be diced into individual assemblies. LED manufacturing is no different. Therefore, it is necessary to form the LED 501 into a mesa structure so that it can be eventually diced into an individual LED assembly. Otherwise, without etching the LED 501 into the mesa structure, when the handling wafer 502 is diced the dicing process (which is typically performed using a laser or a mechanical blade, or both) will cause the semiconductor layers of the LED 501 to crack and may lead to device failure. By etching the semiconductor layers of the LED 501 to form the mesa structure, each individual LED 501 on the handling wafer 502 will have a space separating them from adjacent LEDs where the dicing will occur. This space is also known as the streets 520.

In FIG. 5G, an insulating layer 514 is deposited over the LED 501 and the exposed portions of the bonding layer 513 in the streets adjacent to the LED 501 following etching of the semiconductor layers of the LED 501. Again, as previously discussed in connection with FIGS. 2A and 2B, the insulating layer 514 is preferably a high-quality layer comprising silicon nitride (SiNₓ) or silicon dioxide (SiO2). The insulating layer 514 should also be formed to a sufficient thickness so that no current leakage will occur through the insulating layer 514. In one embodiment, the insulating layer 514 is formed to a thickness between 0.2 μm and 1 μm.

In FIG. 5H, a portion of the insulating layer 514 is etched, exposing a portion of a top surface 505 of the second semiconductor layer 508 of the LED 501. In FIG. 5I, a layer of conductive material 511 is deposited over the insulating layer 514 and the exposed portion of the top surface 505 of the second semiconductor layer. The layer of conductive material 511 can be any material suitable for forming an ohmic contact with the second semiconductor layer 508. In one embodiment, the layer of conductive material 511 comprises a metal, such as gold (Au), silver (Ag), titanium (Ti), platinum (Pt), or aluminum (Al). In another embodiment, the layer of conductive material 511 comprises a conductive compound, such as indium tin oxide (ITO).

In FIG. 5J, a portion of the layer of conductive material 511 is removed to form second electrode 512. The second electrode 512 extends from the surface 505 of the second semiconductor layer 508 down sidewalls 507 of the LED 501 and into the streets 520. The LED assembly shown in FIG. 5J is the same as the LED assembly 300 shown and described in connection with FIGS. 3A-3C, according to one embodiment of the invention.

FIGS. 5K-5M show the additional manufacturing steps to form the LED assembly 400 shown in FIGS. 4A-4C, according to one embodiment of the invention. In FIG. 5K, rather than leaving the portions of the second electrode 512 extending down the sidewalls 507 of the LED 501 as described in FIG. 5J, portions of the layer of conductive material 511 are removed so that the second electrode 512 is only formed on the surface 505 of the second semiconductor layer 508. In FIG. 5L, a second layer of conductive material 519 is deposited over the LED 501, the second electrode 502, and the insulating layer 514. In one embodiment, the second layer of conductive material 519 comprises a conductive material different from the second electrode 512. In one embodiment, the second layer of conductive material 519 is thicker than the second electrode 512.

In FIG. 5M, a portion of the second layer of conductive material 519 is removed to form a third electrode 516. The third electrode 516 is electrically coupled to the second electrode 512, and extends from the second electrode 512 over the surface 505 of the second semiconductor layer 508, down sidewalls 507 of the LED 501, and into the streets 520. In one embodiment, because the second layer of conductive material 519 was previously formed thicker than the second electrode 512, the third electrode 516 formed from the second layer of conductive material 519 will also be thicker than the second electrode 512. In one embodiment, the ratio of the thickness of the third electrode 516 compared to the thickness of the second electrode 512 is 2:1, or greater. In another embodiment, the ratio of the thickness of the third electrode 516 compared to the thickness of the second electrode 512 is 5:1, or greater. The LED assembly shown in FIG. 5M is the same as the LED assembly 400 shown and described in connection with FIGS. 4A-4C, according to another embodiment of the invention.

As shown in FIGS. 5K-5M, the LED assembly 400 requires an additional metal layer deposition and removal step to form the third electrode 516. However, any additional cost and time for manufacturing will be offset by the resulting improvement in reliability by using a material for the third electrode 516 suitable for forming a good contact with the insulating layer 514, and the third electrode 516 can be formed thicker than the second electrode 512 to further reduce the sheet resistance of the electrodes 512 and 516 and improve the current spreading of the LED assembly during device operation.

Other objects, advantages and embodiments of the various aspects of the present invention will be apparent to those who are skilled in the field of the invention and are within the scope of the description and the accompanying Figures. For example, but without limitation, structural or functional elements might be rearranged, or method steps reordered, consistent with the present invention. Similarly, principles according to the present invention could be applied to other examples, which, even if not specifically described here in detail, would nevertheless be within the scope of the present invention.

What is claimed is:

1. A vertical light emitting diode (LED) assembly comprising:
an LED comprising a light emitting layer disposed between a first layer having a first conductivity type and a second layer having a second conductivity type;
a substrate bonded to the LED;
a first electrode disposed between the LED and the substrate, wherein the first electrode is electrically coupled to the first layer;
a second electrode disposed on a surface of the second layer opposite the first layer and electrically coupled to the second layer, wherein the second electrode extends over one or more sidewalls of the LED; and
an insulating layer disposed between the second electrode and the one or more sidewalls.

2. The vertical LED assembly of claim 1, wherein the second electrode extends over each of the one or more sidewalls of the LED.

3. The vertical LED assembly of claim 1, wherein the second electrode extends laterally beyond one or more sidewalls of the LED assembly.

4. The vertical LED assembly of claim 2, wherein the second electrode extends laterally beyond each of the one or more sidewalls of the LED assembly.

5. The vertical LED assembly of claim 1, wherein the first layer and the second layer comprise GaN.

6. The vertical LED assembly of claim 1 wherein the insulating layer has a thickness between 0.2 μm to 1 μm.

7. The vertical LED assembly of claim 1, wherein the first electrode comprises a material having an optical reflectivity greater than 80%.

8. The vertical LED assembly of claim 1, wherein the first electrode comprises Ag.

9. The vertical LED assembly of claim 1, wherein the insulating layer comprises a material selected from SiNₓ and SiO₂.

10. A vertical light emitting diode (LED) assembly comprising:
an LED comprising a light emitting layer disposed between a first layer having a first conductivity type and a second layer having a second conductivity type;
a substrate bonded to the LED;
a first electrode disposed between the LED and the substrate, wherein the first electrode is electrically coupled to the first layer;
a second electrode disposed on a surface of the second layer opposite the first layer and electrically coupled to the second layer;
a third electrode disposed over one or more sidewalls of the LED and electrically coupled to the second electrode; and
an insulating layer disposed between the third electrode and the one or more sidewalls.

11. The vertical LED assembly of claim 10, wherein the third electrode is disposed over each of the one or more sidewalls of the LED.

12. The vertical LED assembly of claim 10, wherein third electrode extends laterally beyond one or more sidewalls of the LED assembly.

13. The vertical LED assembly of claim 11, wherein the third electrode extends laterally beyond each of the one or more sidewalls of the LED assembly.

14. The vertical LED assembly of claim 10, wherein the second electrode and the third electrode comprise different materials.

15. The vertical LED assembly of claim 14, wherein the second electrode and the third electrode comprise materials selected from the group consisting of Ag, Au, Al, Pt, Ti, and ITO.

16. The vertical LED assembly of claim 10, wherein the third electrode has a thickness greater than a thickness of the second electrode.

17. The vertical LED assembly of claim 16, wherein the ratio of the thickness of the third electrode compared to the thickness of the second electrode is 2:1, or greater.

18. The vertical LED assembly of claim 16, wherein the ratio of the thickness of the third electrode compared to the thickness of the second electrode is 5:1, or greater.

19. The vertical LED assembly of claim 10, wherein the first layer and the second layer comprise GaN.

20. The vertical LED assembly of claim 10, wherein the insulating layer has a thickness between 0.2 μm to 1 μm.

21. The vertical LED assembly of claim 10, wherein the first electrode comprises a material having an optical reflectivity greater than 80%.

22. The vertical LED assembly of claim 10, wherein the first electrode comprises Ag.

23. The vertical LED assembly of claim 10, wherein the insulating layer comprises a material selected from SiNₓ and SiO₂.
